(19) United States
(12) Patent Application Publication
(10) Pub. No.: US 2007/0134835 A1
(43) Pub. Date: Jun. 14, 2007

(54) SWITCH USING MICRO ELECTRO MECHANICAL SYSTEM

(76) Inventors: Hiroshi Fukuda, Tokyo (JP); Toshiyuki Mine, Fussa (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/566,952

(22) Filed: Dec. 5, 2006

(30) Foreign Application Priority Data
Dec. 6, 2005 (JP) JP2005-351391

(51) Int. Cl. H01L 21/00; H01L 29/84

(52) U.S. Cl. 438/48; 257/415

(57) ABSTRACT

A MEMS switch is provided with a substrate, a diaphragm which is disposed on the substrate with interposing a cavity therebetween and is elastically deformed by electrostatic force, a switch drive electrode disposed on the substrate, and a switch drive electrode disposed on the diaphragm. Further, a charge accumulation electrode is disposed on the diaphragm between the switch drive electrode and the switch drive electrode. When charge is accumulated in the charge accumulation electrode, electrostatic force is generated between the charge accumulation electrode and the switch drive electrode, thereby deforming the diaphragm. Accordingly, a small-sized bistable MEMS switch whose structure is simple, whose holding state is stable for a long period, and which can be easily mounted together with a semiconductor integrated circuit can be realized.

### CROSS-REFERENCE TO RELATED APPLICATION

The present application claims priority from Japanese Patent Application No. JP 2005-351391 filed on Dec. 6, 2005, the content of which is hereby incorporated by reference into this application.

### TECHNICAL FIELD OF THE INVENTION

The present invention relates to a switch using micro electro mechanical systems (MEMS) (hereinafter, called “MEMS switch”). In particular, it relates to a technology effectively applied to a switch for switching signals in a plurality of frequency bands.

### BACKGROUND OF THE INVENTION

A MEMS (micro electro mechanical systems) technology for forming a mechanical sensor such as a pressure sensor or an acceleration sensor and a mechanical actuator such as a minute switch or an oscillator, that is, a miniaturized mechanical component or mechanical system by using a micro-fabrication technology which has realized high performance and large scale integration of a semiconductor integrated circuit has been under development.

The MEMS are roughly classified to a bulk MEMS that is formed by processing a semiconductor substrate itself made of silicon and a surface MEMS that is formed by repeating the deposition and patterning of thin films on a surface of a semiconductor substrate. A technology similar to that for a semiconductor integrated circuit process (semiconductor manufacturing technology) is applied to this surface MEMS.

As one representative application of the MEMS, a MEMS switch (which may be also referred to as MEM (micro electro mechanical) switch) is known. The MEMS switch controls connection and disconnection of an electric signal line or a power supply line (ON/OFF control) utilizing a mechanical switch having a contact. For example, the MEMS switch can also be inserted in a signal line for an RF (radio frequency) signal on an antenna side of a mobile communication device so as to be used as a switch for switching a plurality of high frequency band (multi-mode) signals. Such a MEMS switch is one of a group of MEMS for performing processing of RF signals (generally referred to as RF-MEMS), and it is also called RF-MEMS switch.

Also, optical MEMS which handles not only electric signals but also optical signals have been developed. Among the optical MEMS, especially, an optical switch controlling ON and OFF of optical signal (optical MEMS switch) has been developed.

U.S. Pat. No. 6,635,506 (Patent Document 1) and U.S. Pat. No. 6,667,245 (Patent Document 2) disclose the technology regarding a MEMS switch which controls connection and disconnection by means of an action of an electrostatic force.

Japanese Patent No. 2555922 (Patent Document 3) and Japanese Patent Application Laid-Open Publication No. 2004-160572 (Patent Document 4) disclose the technology for putting a diaphragm in its charged state to hold the same by means of an action of an electrostatic force.

Journal of The Institute of Electronics, Information and Communication Engineers, Volume 87 (No. 11), pp. 919 to 938 (published by The Institute of Electronics, Information and Communication Engineers in November 2004) (Non-Patent Document 1) discloses a technology regarding RF-MEMS and RF-MEMS switch.

### SUMMARY OF THE INVENTION

FIG. 44 and FIG. 45 are sectional views schematically showing a MEMS switch that has been examined by the inventors of the present invention. FIG. 44 shows a non-connected state and FIG. 45 shows a connected state.

The MEMS switch which has been examined by the inventors of the present invention includes a substrate 1, a movable beam (a movable portion or a diaphragm) 2, a pair of (a set) of switch drive electrodes 3 and 4, an input signal line 5, and an output signal line 6. As shown in FIG. 44, the MEMS switch in a non-connected state does not transmit a signal because the input signal line 5 and the output signal line 6 are not in contact with each other. As shown in FIG. 45, when a voltage is applied to the switch electrodes 3 and 4 in the MEMS switch in the non-connected state, the movable beam 2 is deformed by electrostatic force and the input signal line 5 and the output signal line 6 come in contact with each other. By this means, an input terminal In and an output terminal Out are put in a conductive state to each other and the MEMS switch is put in a connected state where it can transmit a signal. Note that a plurality of the MEMS switches can be formed, for example, on one chip by using the semiconductor manufacturing technology.

Such a MEMS switch can be used in a line path (signal line) that transmits a signal processed by a semiconductor integrated circuit or a path (signal line) that transmits a signal inputted externally (for example, through an antenna) to a semiconductor integrated circuit. However, for example, when a plurality of MEMS switches formed on one chip and a plurality of semiconductor integrated circuits formed on one chip are used in combination, since these chips are separated chips, it is difficult to reduce the size of a whole system. Also, since the MEMS switches and the semiconductor integrated circuits are formed on a semiconductor substrate made of silicon or the like by using the semiconductor manufacturing technology, it is thought that both are integrated on one substrate in a monolithic manner. For example, it is thought that a MEMS switch can be formed on a semiconductor integrated circuit through a so-called Cu-damascene wiring process.

Further, when a MEMS switch is inserted and used in a signal line for an RF signal on an antenna side of a mobile communication device such as a cellular phone, the MEMS switch has to hold its connected (or non-connected) state during a wait state where an operation state at one frequency band is switched to another frequency band. Therefore, in the MEMS switch which has been examined by the inventors of the present invention shown in FIG. 44 and FIG. 45, a voltage applied to the switch drive electrodes 3 and 4 (a voltage for driving the MEMS switch) for holding a connected state where the input signal line 5 and the output signal line 6 are electrically connected to each other is, for example, about 30 to 50 V which is higher than a power supply voltage (for example, about 5 V) of the semiconductor integrated circuit, and a proper voltage boosting circuit for generating high voltage is therefore required.

Furthermore, when an RF signal with large power is handled, a high voltage is required in order to hold the connection (or non-connection) of the switch with a stronger electrostatic force. More specifically, in order to prevent the switch from being driven (being changed to an ON/OFF state) due to deformation (vibration) of the movable beam 2 caused by the RF signal flowing in the input signal line 5, it is necessary to apply a voltage for generating the electrostatic force for suppressing the deformation (vibration) of the movable beam 2 to the switch drive electrodes 3 and 4.

Therefore, since the voltage boosting circuit has to continue to be driven in order to hold the MEMS switch in a connected state during the above-described waiting state, power consumption increases. The increase in the power consumption causes a problem that a practically sufficient waiting time cannot be secured by one battery charging in, for example, a mobile communication device. Also, such a problem arises that it is necessary to additionally provide a transistor with high withstand voltage for controlling “application” or “non-application” of a high voltage to the MEMS switch in order to drive the MEMS switch from a connected state to a non-connected state.

Therefore, various bistable MEMS switches as described below are proposed. The term “bistable” here means such a property that each of a connected state and a non-connected state continues stably without particularly applying external force to the switch. The bistable MEMS switch can mechanically realize two stable states. It is also possible to electrically realize the bistable property.

For example, a MEMS switch having a first switch, a pair of switch drive electrodes provided near the first switch, and a second switch electrically connected to the switch drive electrodes can be provided. First, a voltage is applied to the switch drive electrodes to accumulate the charge. It is assumed that, in this state, electrostatic force is generated between the switch drive electrodes, and the first switch is put in an ON state. Next, even if the second switch is put in a non-connected state, the charge is held in the switch drive electrodes, and the first switch can continue to be driven (be in an ON state) by electrostatic field generated by the held charge. In this case, the second switch may be an electrical switch.

However, both the mechanical and electrical bistable MEMS switches are large in size, and they have complicated structures. Also, it is difficult to mount the bistable MEMS switch together with a semiconductor integrated circuit due to specialty of the structure, the material, and others.

For example, in an optical MEMS switch described in Japanese Patent No. 2555922 (Patent Document 3) and Japanese Patent Application Laid-Open Publication No. 2004-160572 (Patent Document 4), a structure for holding the charge by using a principle of a semiconductor memory such as so-called flash memory or EEPROM is proposed. In the structures disclosed in the Patent Documents 3 and 4, a charge accumulation electrode is provided on a charge injection electrode with interposing an insulating film therebetween, and a diaphragm (a movable portion) made of an electrically conductive material is provided near the charge accumulation electrode with interposing a cavity (gap) therebetween. Therefore, in this optical MEMS switch, charge is injected in the charge accumulation electrode and the diaphragm is driven and held by the electrostatic force of the injected charge.

In such a structure, however, since the diaphragm itself is made of an electrically conductive material, it is difficult to control an electric signal, and since charge accumulated in the charge accumulation electrode leaks from a tunnel insulating film, electrostatic force gradually decreases and it becomes impossible to hold the diaphragm.

For example, such a problem occurs in the RF-MEMS switch that insertion resistance loss must be suppressed and wearing of a switch contact portion (a contact point) due to switching drive must be suppressed. Therefore, it is necessary to take such measures as enlargement of an area of the contact, use of gold (Au) excellent in wear resistance, and others.

However, when the RF-MEMS is mounted together with a semiconductor integrated circuit as described above, if gold diffuses in the semiconductor integrated circuit portion, transistor performance is significantly degraded, and therefore, it is difficult to integrate the RF-MEMS with the semiconductor integrated circuit.

An object of the present invention is to provide a small-sized MEMS switch which can be driven with low voltage.

Another object of the present invention is to provide a bistable MEMS switch whose holding state is stable for a long term.

Another object of the present invention is to provide a bistable MEMS switch suitable for the mixed mounting with a semiconductor integrated circuit.

The above and other objects and novel characteristics of the present invention will be apparent from the description of this specification and the accompanying drawings.

The typical ones of the inventions disclosed in this application will be briefly described as follows.

The present invention provides a switch where a signal transmits through a signal line portion according to electrical connection or disconnection of a first signal line and a second signal line, the signal line portion and a pair of switch drive electrodes are arranged so that they do not overlap with each other in a region parallel to a substrate, and a movable portion is elastically deformed by electrostatic field generated by the accumulation of charge in a charge accumulation electrode, thereby changing and holding a connection state of the first signal line and the second signal line.

The effects obtained by typical aspects of the present invention will be briefly described below.

According to the present invention, a small-sized MEMS switch or bistable MEMS switch which can be driven with low voltage can be provided.

### BRIEF DESCRIPTIONS OF THE DRAWINGS

FIG. 1 is a plan view schematically showing a MEMS switch according to an embodiment of the present invention;

FIG. 2 is a sectional view of the MEMS switch taken along line A-A′ in FIG. 1, which shows an initial state of the MEMS switch;

FIG. 3 is a sectional view of the MEMS switch taken along line A-A′ in FIG. 1, which shows a charge injection state of the MEMS switch;

FIG. 4 is a sectional view of the MEMS switch taken along line A-A′ in FIG. 1, which shows a charge holding state of the MEMS switch;

FIG. 5 is a sectional view of the MEMS switch taken along line B-B′ in FIG. 1, which shows an initial state of the MEMS switch;

FIG. 6 is a sectional view of the MEMS switch taken along line B-B′ in FIG. 1, which shows a charge injection state of the MEMS switch;

FIG. 7 is a sectional view of the MEMS switch taken along line B-B′ in FIG. 1, which shows a charge holding state of the MEMS switch;

FIG. 8 is a timing chart schematically showing a drive voltage signal of the MEMS switch according to an embodiment of the present invention;

FIG. 9 is a sectional view schematically showing the MEMS switch with another configuration according to an embodiment of the present invention;

FIG. 10 is a sectional view schematically showing a manufacturing process of the MEMS switch according to an embodiment of the present invention;

FIG. 11 is a sectional view schematically showing the manufacturing process of the MEMS switch subsequent to the step shown in FIG. 10;

FIG. 12 is a sectional view schematically showing the manufacturing process of the MEMS switch subsequent to the step shown in FIG. 11;

FIG. 13 is a sectional view schematically showing the manufacturing process of the MEMS switch subsequent to the step shown in FIG. 12;

FIG. 14 is a sectional view schematically showing the manufacturing process of the MEMS switch subsequent to the step shown in FIG. 13;

FIG. 15 is a sectional view schematically showing the manufacturing process of the MEMS switch subsequent to the step shown in FIG. 14;

FIG. 16 is a plan view schematically showing the MEMS switch with another configuration according to an embodiment of the present invention;

FIG. 17 is a sectional view of the MEMS switch taken along line C-C′ in FIG. 16, which shows an initial state thereof;

FIG. 18 is a sectional view of the MEMS switch taken along line C-C′ in FIG. 16, which shows a connected state thereof;

FIG. 19 is a plan view schematically showing a MEMS switch according to another embodiment of the present invention;

FIG. 20 is a sectional view of the MEMS switch taken along line D-D′ in FIG. 19, which shows an initial state thereof;

FIG. 21 is a sectional view of the MEMS switch taken along line D-D′ in FIG. 19, which shows a charge injection state thereof;

FIG. 22 is a sectional view of the MEMS switch taken along line D-D′ in FIG. 19, which shows a charge holding state thereof;

FIG. 23 is a sectional view schematically showing the manufacturing process of the MEMS switch according to another embodiment of the present invention;

FIG. 24 is a sectional view schematically showing the manufacturing process of the MEMS switch subsequent to the step shown in FIG. 23;

FIG. 25 is a sectional view schematically showing the manufacturing process of the MEMS switch subsequent to the step shown in FIG. 24;

FIG. 26 is a sectional view schematically showing the manufacturing process of the MEMS switch subsequent to the step shown in FIG. 25;

FIG. 27 is a sectional view schematically showing the manufacturing process of the MEMS switch subsequent to the step shown in FIG. 26;

FIG. 28 is a sectional view schematically showing the manufacturing process of the MEMS switch subsequent to the step shown in FIG. 27;

FIG. 29 is a sectional view schematically showing the manufacturing process of the MEMS switch subsequent to the step shown in FIG. 28;

FIG. 30 is a sectional view schematically showing the manufacturing process of the MEMS switch subsequent to the step shown in FIG. 29;

FIG. 31 is a sectional view of the MEMS switch according to another embodiment of the present invention, which schematically shows an initial state thereof and corresponds to the section of the MEMS switch taken along line A-A′ in FIG. 1;

FIG. 32 is a sectional view of the MEMS switch according to another embodiment of the present invention, which schematically shows a charge injection state thereof and corresponds to the section of the MEMS switch taken along line A-A′ in FIG. 1;

FIG. 33 is a sectional view of the MEMS switch according to another embodiment of the present invention, which schematically shows a charge holding state thereof and corresponds to the section of the MEMS switch taken along line A-A′ in FIG. 1;

FIG. 34 is a sectional view of the MEMS switch according to another embodiment of the present invention, which schematically shows a charge re-injection state thereof and corresponds to the section of the MEMS switch taken along line A-A′ in FIG. 1;

FIG. 35 is a sectional view of the MEMS switch according to another embodiment of the present invention, which schematically shows an initial state thereof and corresponds to the section of the MEMS switch taken along line B-B′ in FIG. 1;

FIG. 36 is a sectional view of the MEMS switch according to another embodiment of the present invention, which schematically shows a charge injection state thereof and corresponds to the section of the MEMS switch taken along line B-B′ in FIG. 1;

FIG. 37 is a sectional view of the MEMS switch according to another embodiment of the present invention, which schematically shows a charge holding state thereof and corresponds to the section of the MEMS switch taken along line B-B′ in FIG. 1;

FIG. 38 is a sectional view of the MEMS switch according to another embodiment of the present invention, which schematically shows a charge re-injection state thereof and corresponds to the section of the MEMS switch taken along line B-B′ in FIG. 1;

FIG. 39 is a timing chart schematically showing a drive voltage signal of the MEMS switch according to another embodiment of the present invention;

FIG. 40 is an explanatory diagram schematically showing a whole configuration of an RF front end module according to another embodiment of the present invention;

FIG. 41 is a plan view schematically showing a main portion of a switch array shown in FIG. 40;

FIG. 42 is a sectional view taken along line E-E′ in FIG. 41;

FIG. 43 is an explanatory diagram schematically showing a whole configuration of a system LSI according to another embodiment of the present invention;

FIG. 44 is a sectional view schematically showing a MEMS switch which has been examined by the inventors of the present invention, which shows a non-connected state; and

FIG. 45 a sectional view schematically showing the MEMS switch which has been examined by the inventors of the present invention, which shows a connected state.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

First, a structure and a drive principle of a MEMS switch according to a first embodiment of the present invention will be explained. The MEMS switch according to the first embodiment can be applied as a switch used for determining whether or not transmission of a signal should be performed.

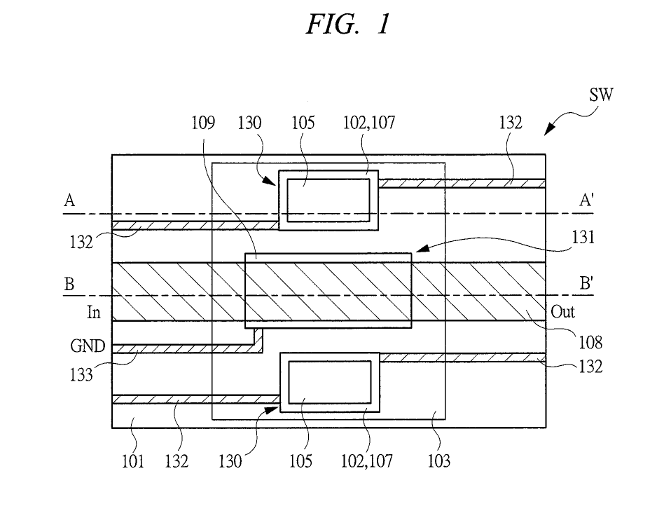

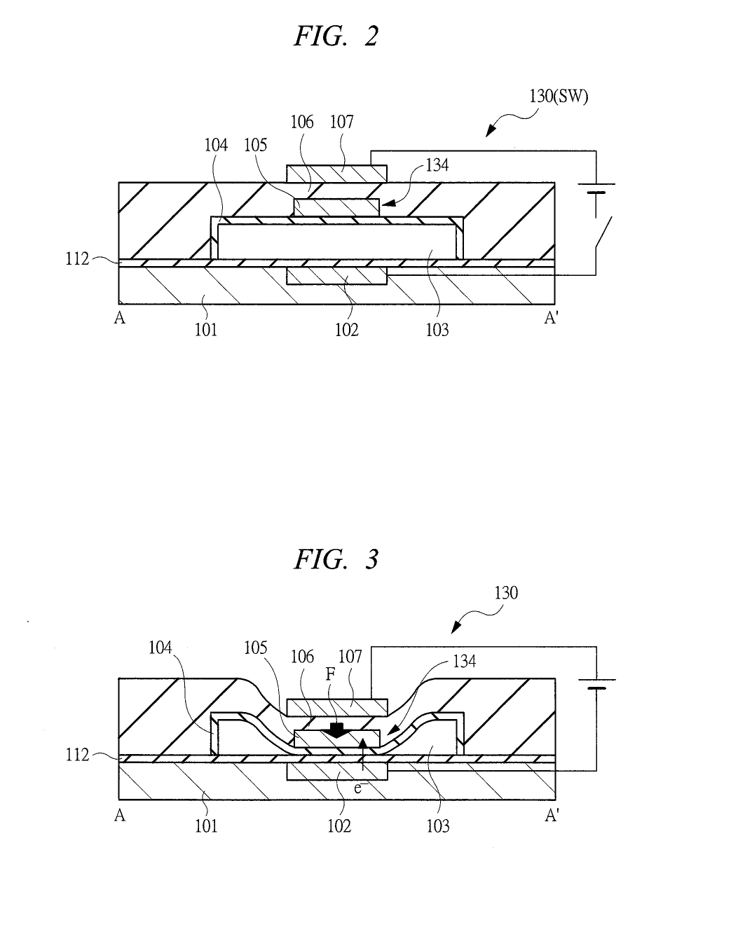

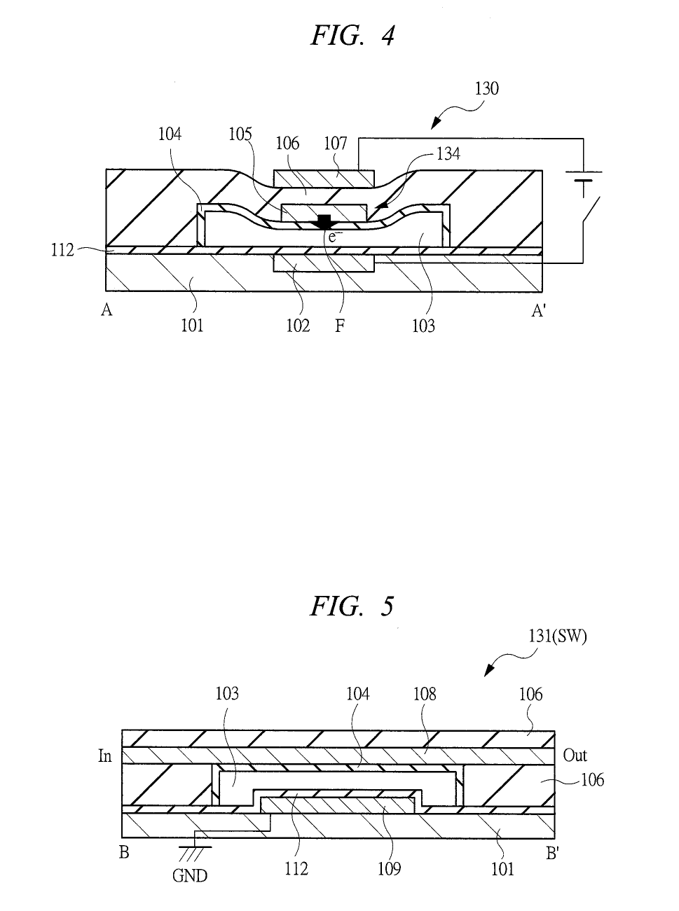

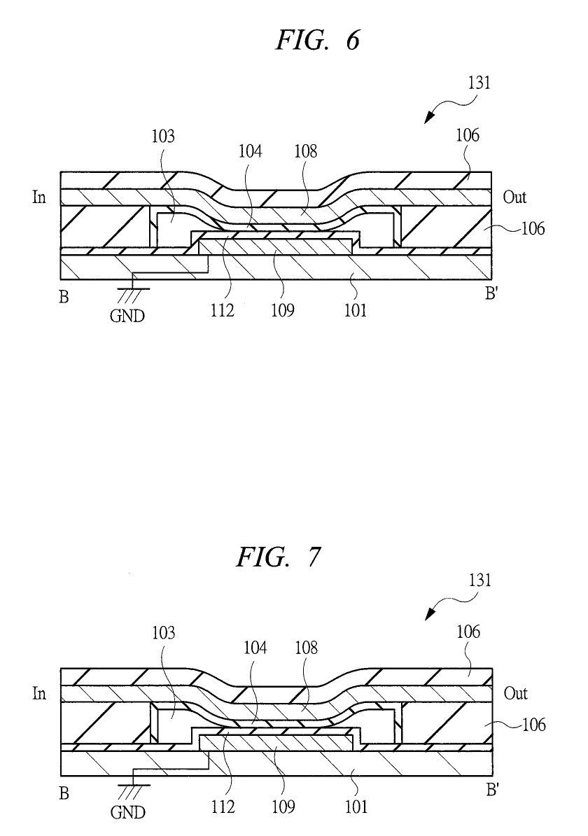

FIG. 1 is a plan view schematically showing the MEMS switch according to the first embodiment of the present invention. FIG. 2 to FIG. 4 are sectional views taken along line A-A′ in FIG. 1 for explaining a drive principle of the MEMS switch according to the first embodiment of the present invention, wherein FIG. 2 shows an initial state of the MEMS switch, FIG. 3 shows a charge injection state thereof, and FIG. 4 shows a charge holding state thereof. FIG. 5 to FIG. 7 are sectional views of the MEMS switch taken along line B-B′ in FIG. 1 for explaining the drive principle of the MEMS switch according to the first embodiment of the present invention, wherein FIG. 5 shows an initial state of the MEMS switch, FIG. 6 shows a charge injection state thereof, and FIG. 7 shows a charge holding state thereof. In FIG. 1, for easy explanation, some of constituent components are shown transparently and a signal line 108, wires 132, and a wire 133 are shown with hatching.

As shown in FIG. 1, two drive portions 130 and one signal line portion 131 are formed on a substrate 101 of a MEMS switch SW. Also, a cavity (gap) 103 is formed on the substrate 101. The drive portion 130 has a pair (set) of a first switch drive electrode 102 and a second switch drive electrode 107, a charge accumulation electrode 105, and wires 132 for applying a voltage to the switch drive electrodes 102 and 107. Also, the signal line portion 131 has a ground electrode 109 also serving as a signal line, a signal line 108 for signal transmission, and a wire 133 electrically connecting the ground electrode 109 and the ground GND. A signal is transmitted from an input terminal In to an output terminal Out via the signal line 108.

As shown in FIG. 2 to FIG. 4, in the drive portion 130, the switch drive electrode 102 is provided in a main surface of the substrate 101 and a tunnel insulating film (first insulating film) 112 is provided on the substrate 101 so as to cover the switch drive electrode 102. The switch drive electrode 102 may be formed on the substrate 101. Though described later, the switch drive electrode 102 also serves as an electrode for injecting charge (charge injection electrode) into the charge accumulation electrode 105.

The charge accumulation electrode 105 is provided above the switch drive electrode 102 with interposing the cavity 103 therebetween. The cavity 103 is formed so as to be surrounded by the tunnel insulating film 112 and a tunnel insulating film (second insulating film) 104 positioned below the charge accumulation electrode 105, and a planar size thereof is about 100 μm×100 μm, for example. Further, a switch drive electrode 107 is provided above the charge accumulation electrode 105 with interposing an interlayer insulating film 106 therebetween. Planar sizes of the switch drive electrodes 102 and 107 are, for example, about several tens to a hundred μm×several tens μm, respectively. The interlayer insulating film 106 is thicker than the tunnel insulating film 112 and the tunnel insulating film 104, and a film thickness thereof is, for example, about 100 nm and both of the tunnel insulating film 112 and the tunnel insulating film 104 have a thickness of about 10 to 20 nm. In the first embodiment, a case where the MEMS switch SW has the tunnel insulating film 104 and the tunnel insulating film 112 is shown. However, it is also possible to design the MEMS switch SW to have at least one of the insulating films.

Further, the MEMS switch SW has a diaphragm (a movable portion) 134 composed of the interlayer insulating film 106 elastically deformed by external force such as electrostatic force. The switch drive electrode 107 and the charge accumulation electrode 105 are provided for the diaphragm 134.

As shown in FIG. 5 to FIG. 7, in the signal line portion 131, the ground electrode 109 is provided on the main surface of the substrate 101 and a tunnel insulating film 112 is provided on the substrate 101 so as to cover the ground electrode 109. The signal line 108 is provided above the ground electrode 109 with interposing the cavity 103 therebetween. The cavity 103 is formed so as to be surrounded by the tunnel insulating film 112 and the tunnel insulating film 104 positioned below the signal line 108. Further, the interlayer insulating film 106 is provided so as to protect the signal line 108. The ground electrode 109 is electrically connected to the ground GND. Also, the ground electrode 109 may be formed on the main surface of the substrate 101.

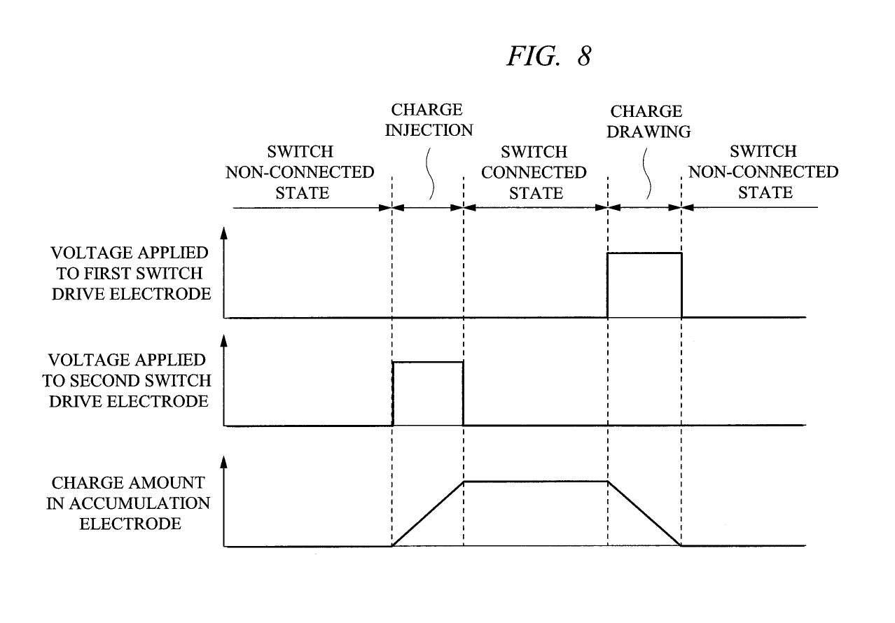

FIG. 8 is a timing chart schematically showing a drive voltage signal of the MEMS switch according to the first embodiment, where an applied voltage to the first switch drive electrode 102, an applied voltage to the second switch drive electrode 107, and a charge amount of the charge accumulation electrode 105 according to elapsed time are shown.

As shown in FIG. 2 and FIG. 5, in a basic attitude (an initial state) of the MEMS switch SW according to the first embodiment, the switch drive electrode 102 serving as a charge injection electrode and the tunnel insulating film 104 are put in a non-contact state with interposing the cavity 103 therebetween in a state where a voltage is not applied to the switch drive electrodes 102 and 107. In the first embodiment, a period of a switch non-connected state shown in FIG. 8 is defined as the initial state.

When the MEMS switch SW is in the initial state, the cavity 103 is also present between the signal line 108 and the ground electrode 109. Therefore, a capacitance between the signal line 108 and the ground electrode 109 is very low, and a signal inputted into the input terminal In is directly transmitted to the output terminal Out. More specifically, the input terminal In and the output terminal Out of the signal line 108 are put in an AC connected state and a DC connected state. The term “AC connected state” means a state where an AC-component signal is transmitted, while the term “DC connected state” means a state where a DC-component signal is transmitted.

Subsequently, as shown in FIG. 3, when the switch drive electrode 102 is grounded and positive voltage is applied to the switch drive electrode 107 during the charge injection period in FIG. 8 from the initial state of the MEMS switch, the diaphragm 134 above the cavity 103 is deformed by electrostatic force F and the switch drive electrode 102 serving as the charge injection electrode and the charge accumulation electrode 105 contact with each other via the tunnel insulating films 112 and 104. In this case, electrons are injected from the switch drive electrode 102 serving as the charge injection electrode into the charge accumulation electrode 105 via the tunnel insulating films 112 and 104.

At this time, as shown in FIG. 6, the signal line 108 and the ground electrode 109 are electrically connected to each other via the tunnel insulating film 104 and the tunnel insulating film 112. Therefore, a capacitance between the signal line 108 and the ground GND is increased, and a signal is not transmitted between the input terminal In and the output terminal Out of the signal line 108 (AC non-connected state), while the input terminal In and the ground GND are put in an AC connected state.

Subsequently, as shown in FIG. 4, when a voltage applied to the switch drive electrodes 102 and 107 is set to 0 V during the switch connected state holding period shown in FIG. 8, the degree of deformation of the diaphragm 134 is decreased, but the deformation of the diaphragm 134 is held by electrostatic force F acting between charges (electrons) accumulated in the charge accumulation electrode 105 and charge with reversed polarity induced in the switch drive electrode 102 serving as the charge injection electrode by the electrostatic field caused by the accumulated charges. That is, the switch drive electrode 102 serving as the charge injection electrode and the charge accumulation electrode 105 are put into a non-contacted state.

Note that the reason why the degree of deformation of the diaphragm 134 is decreased is that electrons leaks from the charge accumulation electrode 105 to the switch drive electrode 102 serving as the charge injection electrode via the tunnel insulating films 104 and 112. However, when the switch drive electrode 102 serving as the charge injection electrode and the charge accumulation electrode 105 are in a non-contacted state, the charges in the charge accumulation electrode 105 do not leak to the switch drive electrode 102 serving as the charge injection electrode via the tunnel insulating films 104 and 112. By making the interlayer insulating film 106 between the switch drive electrode 107 and the charge accumulation electrode 105 sufficiently thicker than the tunnel insulating films 104 and 112, current leakage from the charge accumulation electrode 105 to the switch drive electrode 107 is suppressed.

At this time, as shown in FIG. 7, since the ground electrode 109 is provided in the cavity 103 so that the surface thereof is positioned above a surface of the switch drive electrode 102 serving as the charge injection electrode, the signal line 108 and the ground electrode 109 remain in contact via the tunnel insulating film 104 and the tunnel insulating film 112. Accordingly, the AC non-connected state between the input terminal In and the output terminal Out of the signal line 108 is also held semi-permanently.

Subsequently, when a reversed voltage is applied between the switch drive electrodes 102 and 107, namely, a positive voltage is applied to the switch drive electrode 102 and the switch drive electrode 107 is grounded during a charge drawing period shown in FIG. 8, electrons are drawn back to the switch drive electrode 102 serving as the charge injection electrode from the charge accumulation electrode 105 via the tunnel insulating films 104 and 112. By this means, the system returns back to the initial state shown in FIG. 2 and FIG. 5. Even if the switch drive electrode 107 is not grounded and a positive voltage is applied to the switch drive electrode 102, electrons are drawn back to the switch drive electrode 102 serving as the charge injection electrode from the charge accumulation electrode 105 via the tunnel insulating films 104 and 112.

Note that it is preferable that the accumulated charge amount in the charge accumulation electrode 105 in the connected state and the initial state (the non-connected state) after the charge drawing (after returned) is monitored (verified) in the MEMS switch SW according to the first embodiment. This is because the electrostatic force can be controlled in a desired state by applying a voltage to the switch drive electrode 102 or the switch drive electrode 107 while monitoring the accumulated charge amount.

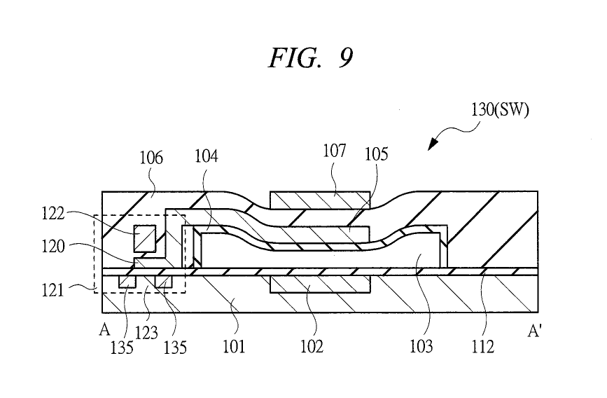

FIG. 9 is a sectional view schematically showing the MEMS switch SW in which a MOS (metal oxide semiconductor) transistor 121 for monitoring is added near the drive portion 130. As shown in FIG. 9, the MOS transistor 121 is connected to the charge accumulation electrode 105 in order to perform the monitoring mentioned above. More specifically, one end 120 of a wire connected to the charge accumulation electrode 105 is inserted in a gate insulating film between a gate electrode 122 and a channel 123 of the MOS transistor 121. By checking a threshold of the MOS transistor 121, an accumulated charge amount can be monitored. Note that a reference numeral 135 denotes a diffusion layer to be a source or a drain of the MOS transistor 121.

In the MEMS switch SW according to the first embodiment, injection and drawing of electrons to and from the charge accumulation electrode 105 are performed using a tunnel current, namely, a so-called Fowler-Nordheim current. Since reduction in time required for injection is not so important in many applications of the MEMS switch, injection utilizing the Fowler-Nordheim current does not cause any problem in many cases. However, injection and drawing of charges can be performed by, for example, additionally providing a transistor for charge injection and utilizing a so-called hot carrier injection instead of utilizing the Fowler-Nordheim current. At this time, the MOS transistor 121 shown in FIG. 9 can be used for the hot carrier injection and charge injection can be performed at high speed.

In the MEMS switch SW according to the first embodiment, a high voltage to be applied may be generated by a voltage boosting circuit formed on the same substrate as the MEMS switch or it may be provided from the outside of the device.

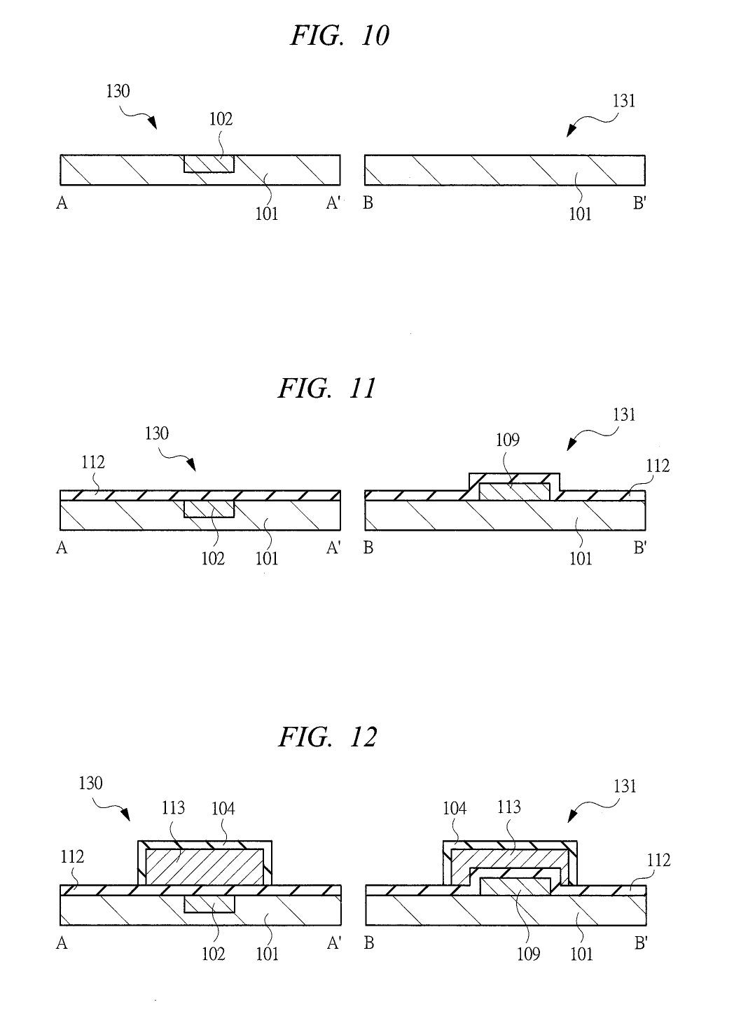

Next, a manufacturing method of the MEMS switch according to the first embodiment will be described. FIG. 10 to FIG. 15 are sectional views schematically showing a manufacturing process of a MEMS switch, and the drive portion 130 (line A-A′ in FIG. 1) and the signal line portion 131 (line B-B′ in FIG. 1) are shown in the respective figures.

As shown in FIG. 10, first, a diffusion layer to be the switch drive electrode 102 is formed in a region of the drive portion 130 of the substrate 101 made of silicon by lithography technique and ion implantation process.

Subsequently, as shown in FIG. 11, after the ground electrode (signal line) 109 made of, for example, polysilicon which is provided in the region of the signal line portion 131 and below the signal line 108 in the cavity 103 formed later is formed, a surface of the substrate 101 is oxidized to form the tunnel insulating film 112 made of silicon oxide with a film thickness of about 10 to 20 nm.

Subsequently, as shown in FIG. 12, after a sacrifice layer 113 made of, for example, polysilicon is formed in a region of the cavity 103 formed later, a surface thereof is oxidized to form the tunnel insulating film 104 made of silicon oxide with a film thickness of about 10 to 20 nm.

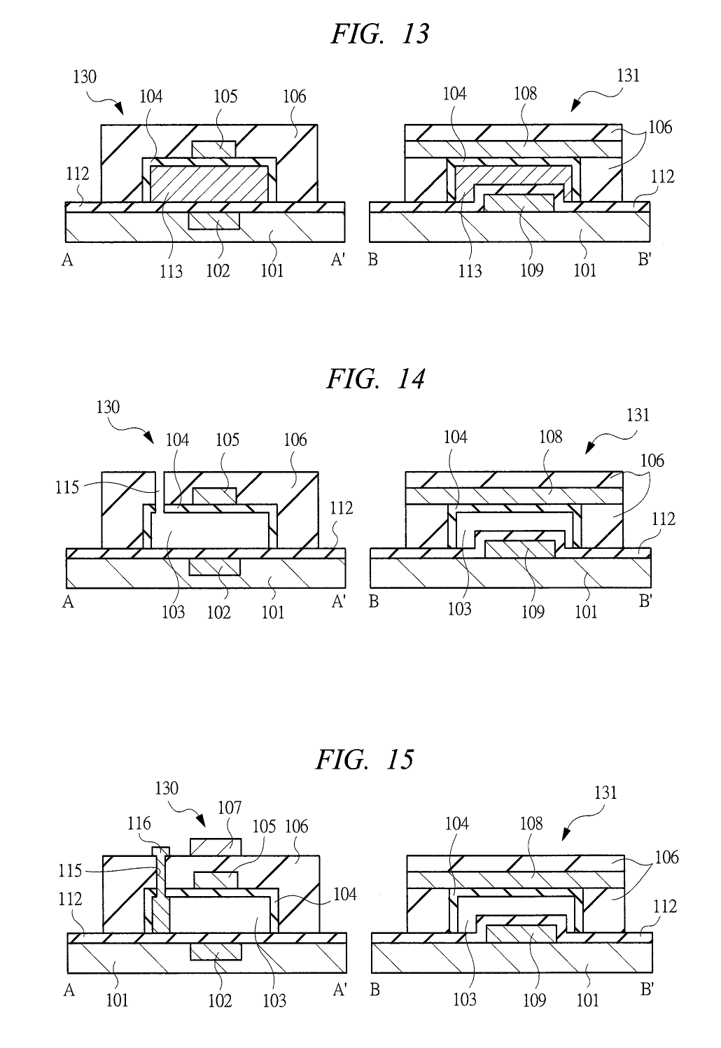

Subsequently, as shown in FIG. 13, the charge accumulation electrode 105 and the signal line 108 are formed in the same layer on the sacrifice layer 113 having the tunnel insulating film 104 formed on the surface thereof, and the interlayer insulating film 106 made of, for example, silicon oxide is further deposited thereon.

Subsequently, as shown in FIG. 14, after an etching hole 115 reaching the sacrifice layer 113 of the drive portion 130 is formed, the sacrifice layer 113 made of polysilicon is etched out via the etching hole 115 to form the cavity 103. The sacrifice layer 113 is removed using XeF₂-gas phase etching in the etching of the sacrifice layer 113. In this case, silicon oxide such as the tunnel insulating films 112 and 104 is hardly etched. Next, after the etching of the sacrifice layer, hydrophobic treatment is performed to an inner surface of the cavity 103. By this means, attachment between the switch drive electrode 102 and the tunnel insulating film 104 is prevented.

Subsequently as shown in FIG. 15, after an insulating film 116 made of, for example, silicon oxide is deposited by CVD process to seal the etching hole 115, a switch drive electrode 107 made of, for example, polysilicon is formed.

All the processes used in the above are included in a scope of a manufacturing process of a so-called standard CMOS (complementary metal oxide semiconductor) semiconductor integrated circuit. Thus, the MEMS switch according to the first embodiment can be manufactured through the semiconductor integrated circuit process (semiconductor manufacturing technology). Accordingly, the MEMS switch according to the first embodiment can be easily integrated with a CMOS semiconductor integrated circuit in a monolithic manner. More specifically, a bistable MEMS switch which is reduced in size, has a relatively simple structure, whose holding state is stable over a long period, and which can be mounted together with a semiconductor integrated circuit can be realized.

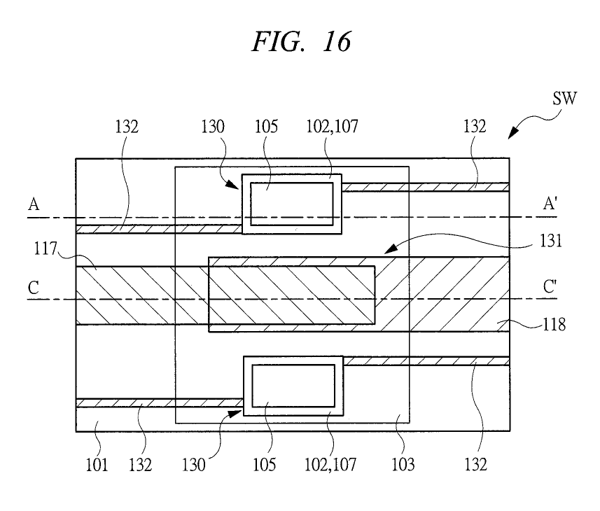

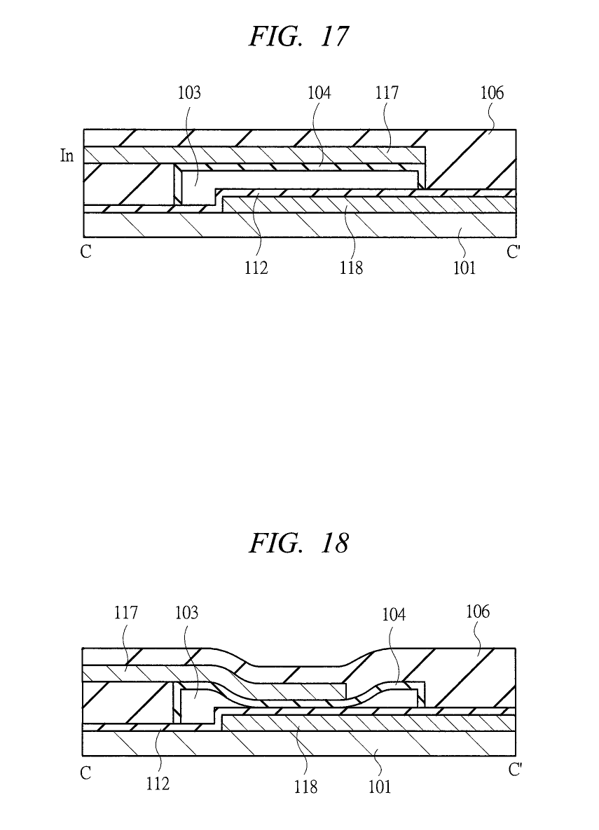

Also, in the MEMS switch SW according to the first embodiment, the configuration that the signal line 108 is put in contact with the ground electrode 109 via the tunnel insulating films 104 and 112 has been described, but the configuration may be modified to another configuration. FIG. 16 is a plan view schematically showing a modified example of the MEMS switch of the first embodiment. FIG. 17 is a sectional view of the MEMS switch taken along line C-C′ in FIG. 16, which shows an initial state (non-contacted state). FIG. 18 is a sectional view of the MEMS switch taken along line C-C′ in FIG. 16, which shows a contacted state. In FIG. 16, some of constituent components are shown transparently for easy explanation, and an upper signal line 117, a lower signal line 118, and wires 132 are shown with hatching. Further, the drive portions 130 in the MEMS switches SW shown in FIG. 1 and FIG. 16 have the same structure, and the sectional view taken along line A-A′ in FIG. 16 corresponds to the sectional view shown in FIG. 2.

The MEMS switch shown in FIG. 16 is largely different from the MEMS switch shown in FIG. 1 in the structure of the signal line portion 131. More specifically, the signal line portion 131 is composed of the signal line 108 and the ground electrode 109 in the MEMS switch shown in FIG. 1, but the signal line portion 131 is composed of the upper signal line 117 and the lower signal line 118 in the MEMS switch shown in FIG. 16. The upper signal line 117 is positioned at the same layer as the charge accumulation electrode 105, and the lower signal line 118 is provided so as to be positioned above the surface of the switch drive electrode 102. Also, as a method for manufacturing the MEMS switch shown in FIG. 16, a semiconductor manufacturing technology similar to that applied to the MEMS switch shown in FIG. 1 can be adopted.

As shown in FIG. 17 and FIG. 18, by the switching drive of the drive portion 130 in the MEMS switch SW shown in FIG. 16, the upper signal line 117 and the lower signal line 118 can be put in an AC connected or AC disconnected state via the tunnel insulating film 112 and the tunnel insulating film 104. Also, after the cavity 103 is formed, by removing the tunnel insulating film 112 and the tunnel insulating film 104 through etching, the upper signal line 117 and the lower signal line 118 can be directly connected so as to put them in a DC connected state.

In the foregoing, the invention made by the inventors of the present invention has been concretely described based on the first embodiment. However, it is needless to say that the present invention is not limited to the foregoing embodiment and various modifications and alterations can be made within the scope of the present invention.

For example, a planar shape of the MEMS switch SW is not limited to those shown in FIG. 1 and FIG. 16 described above. As shown in FIG. 1 and FIG. 16, however, it is preferable that the drive portions 130 and the signal line portion 131 do not overlap with each other in a plan view. Further, as shown in FIG. 1 and FIG. 16, when the drive portions 130 and the signal line portion 131 are provided so that two or more drive portions 130 sandwich the signal line portion 131 in a plan view, parallelism between the signal line portions 131 when they are in contact with each other can be desirably improved.

Also, for example, the manufacturing method and materials for the electrodes or the structural bodies are not limited to those described above, and any modification can be adopted as long as it can realize the basic configuration and the operation principle shown in the first embodiment. For example, electric resistance of the ground electrode 109, the lower signal line 118, the upper signal line 117, and the others can be reduced by using metal such as tungsten or aluminum for them. Also, the charge accumulation electrode 105 can be made of various electret materials such as an organic material and a nitrogen oxide film instead of metal. The reduction in the drive voltage can be achieved by reducing rigidity of the diaphragm 134 on the cavity 103. It is also possible to adopt the thinning of the diaphragm 134 and the introduction of a so-called corrugated shape to a peripheral portion of the diaphragm 134.

Further, for example, by forming the ground electrode 109 or the lower signal line 118 and the switch drive electrode 102 from the same thin film layer (for example, a diffusion layer formed on a surface of the substrate), the structure of the MEMS switch SW can be simplified. When the contact between the switch drive electrode 102 and the insulating film can be held for a practical term even if leakage occurs, the contact between the signal line 108 and the ground electrode 109 or the contact between the upper signal line 117 and the lower signal line 118 is also held.

Furthermore, the charge accumulation electrode 105 may be provided on the substrate 101 instead of the diaphragm 134.

As described above, according to the first embodiment, it is possible to realize a small-sized bistable MEMS switch having a simple structure, in which a holding state is stable for a long term and which can be easily mounted together with a semiconductor integrated circuit. Also, since the signal line and the switch drive electrode have independent structures from each other, a high frequency signal (RF signal) applied to the signal line does not adversely affect the driving of the switch and the reliability of the MEMS switch can be improved.

### Second Embodiment

In a “switch”, in general, two points of that insertion loss is small and that cutoff characteristic is excellent (a so-called ON/OFF ratio is large) are important. Further, in a mechanical switch having a diaphragm and a signal line portion, it is important to suppress mechanical damage (wearing or the like) of the signal line portion. A MEMS switch which mechanically cuts off a signal line such as that shown in the first embodiment is excellent in cutoff characteristic, but it is necessary to adopt a material which is small in electric resistance and has excellent cutoff characteristic for the signal line or the electrode in order to suppress the insertion loss and mechanical damage. A representative metal having such characteristics is, for example, gold (Au).

Accordingly, it is thought that gold (Au) is used as a material of the signal line 108 of the first embodiment. However, the structure shown in the first embodiment is preferably formed using a semiconductor manufacturing technology. In this case, since gold (Au) having large diffusion coefficient adversely influences a transistor (for example, threshold fluctuation), it is considerably difficult to introduce rare metal such as gold (Au) into the manufacturing process. More specifically, when the switch is mounted together with a semiconductor integrated circuit, it is not realistic to use gold as a material of the charge accumulation electrode 105 and the signal line 108 shown in FIG. 1, for example. The second embodiment is to solve such a problem.

First, a structure and a drive principle of a MEMS switch according to a second embodiment of the present invention will be described. The MEMS switch according to the second embodiment can be applied as a switch used for determining whether or not transmission of a signal is performed.

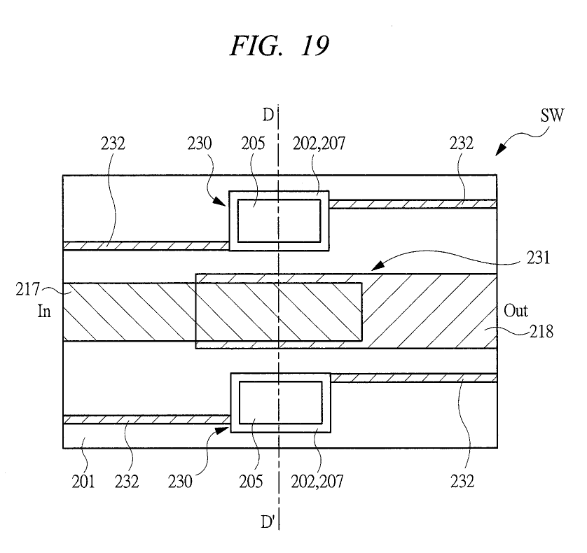

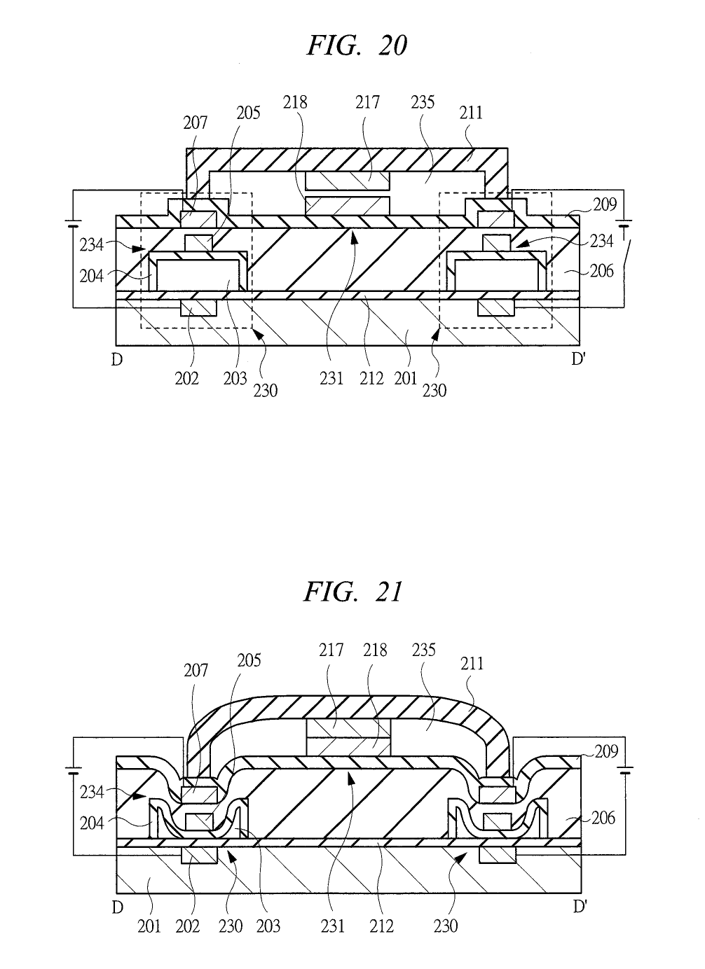

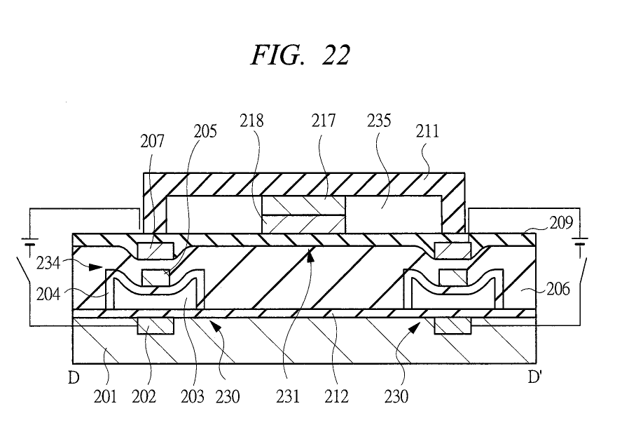

FIG. 19 is a plan view schematically showing the MEMS switch according to the second embodiment of the present invention. FIG. 20 to FIG. 22 are sectional views taken along line D-D′ in FIG. 19 for describing a drive principle of the MEMS switch according to the second embodiment of the present invention, wherein FIG. 20 shows an initial state of the MEMS switch, FIG. 21 shows a charge injection state thereof, and FIG. 22 shows a charge holding state thereof. In FIG. 19, some of constituent components are shown transparently for easy explanation, and an upper signal line 217, a lower signal line 218, and wires 232 are shown with hatching. Basically, the planar arrangement of the drive portion 230 and the signal line potion 231 is not so largely different from that of the drive portion 130 and the signal line portion 131 in the first embodiment.

As shown in FIG. 19, two drive portions 230 and one signal line portion 231 are formed on a substrate 201 of the MEMS switch SW. The drive portion 230 has switch drive electrodes 202 and 207, a charge accumulation electrode 205, and wires 232 for applying a voltage to the switch drive electrodes 202 and 207. Also, the signal line portion 231 has an upper signal line 217 and a lower signal line 218. A signal is transmitted from an input terminal In on the upper signal line 217 side to an output terminal Out on the lower signal line 218 side.

Also, as shown in FIG. 20 to FIG. 22, in the drive portion 230, a switch drive electrode 202 is provided on a main surface of the substrate 201 and a tunnel insulating film 212 is provided on the substrate 201 so as to cover the switch drive electrode 202. The switch drive electrode 202 also serves as a charge injection electrode for injecting charge into the charge accumulation electrode 205.

The charge accumulation electrode 205 is provided above the switch drive electrode 202 with interposing a cavity (gap) 203 therebetween. The cavity 203 is formed so as to be surrounded by the tunnel insulating film 212 and the tunnel insulating film 204 positioned below the charge accumulation electrode 205. Also, a switch drive electrode 207 is provided above the charge accumulation electrode 205 with interposing an interlayer insulating film 206 therebetween.

Whole surfaces of the switch drive electrode 207 and the interlayer insulating film 206 are covered with a protective film 209 made of, for example, silicon nitride. Though described later, the protective film 209 has a function to prevent gold (Au) provided thereon from diffusing through the protective film 209.

Also, a lower signal line 218 is provided on the protective film 209 in the signal line portion 231. A doubly-supported beam 211 is provided on the two drive portions 230 so as to cross the lower signal line 218. An upper signal line 217 opposed to the lower signal line 218 is provided below the doubly-supported beam 211.

As shown in FIG. 20, in a basic attitude (an initial state) of the MEMS switch SW according to the second embodiment, no voltage is applied to the switch drive electrodes 202 and 207 and no charge is accumulated in the charge accumulation electrode 205. In the initial state, the switch drive electrode 202 serving as the charge injection electrode and the tunnel insulating film 204 are put in a non-contacted state with interposing the cavity 203 therebetween. Also, when the MEMS switch SW is in the initial state, a cavity (gap) 235 is present also between the upper signal line 217 and the lower signal line 218. That is, the upper signal line 217 and the lower signal line 218 are in a cutoff state.

Subsequently, as shown in FIG. 21, when the switch drive electrode 202 is grounded and a positive voltage is applied to the switch drive electrode 207 from the initial state of the MEMS switch SW, the whole diaphragm 234 above the cavity 203 is deformed by electrostatic force and the switch drive electrode 202 serving as the charge injection electrode and the charge accumulation electrode 205 contact with each other via the tunnel insulating films 212 and 204. In this case, electrons are injected from the switch drive electrode 202 to the charge accumulation electrode 205 via the tunnel insulating films 212 and 204.

At this time, the upper signal line 217 and the lower signal line 218 are electrically connected to each other, and the upper signal line 217 and the lower signal line 218 are put in a conductive state to each other and a signal inputted into the input terminal In is outputted to the output terminal Out. More specifically, the input terminal In and the output terminal Out of the signal line 108 are put in an AC connected state and DC connected state.

Subsequently, as shown in FIG. 22, when voltage applied to the switch drive electrodes 202 and 207 is set to 0 V, the degree of deformation of the diaphragm 234 is decreased, but the deformation of the diaphragm 234 is held by electrostatic force acting between charges (electrons) accumulated in the charge accumulation electrode 205 and charge with reversed polarity induced in the switch drive electrode 202 serving as the charge injection electrode by electrostatic field caused by the accumulated charges. That is, the switch drive electrode 202 serving as the charge injection electrode and the charge accumulation electrode 205 are put into a non-contacted state.

Note that the reason why the degree of deformation of the diaphragm 234 is decreased is that electrons leak from the charge accumulation electrode 205 to the switch drive electrode 202 via the tunnel insulating films 204 and 212. However, when the switch drive electrode 202 and the charge accumulation electrode 205 are in a non-contacted state, charges in the charge accumulation electrode 205 do not leak to the switch drive electrode 202 via the tunnel insulating films 204 and 212. By making the interlayer insulating film 206 between the switch drive electrode 207 and the charge accumulation electrode 205 sufficiently thicker than the tunnel insulating films 204 and 212, current leakage from the charge accumulation electrode 205 to the switch drive electrode 207 is suppressed.

As the diaphragm 234 moves toward the substrate 201, the doubly-supported beam 211 also moves in the direction toward the substrate 201, and the upper signal line 217 and the lower signal line 218 contact with each other. In this case, surfaces of the upper wire 217 and the lower wire 218 are covered with gold or material containing gold. Therefore, wearing of the upper signal line 217 and the lower signal line 218 due to the contact therebetween is significantly reduced.

When the degree of deformation is decreased due to reduction of electrostatic attractive force due to leakage of electrons from the charge accumulation electrode 205 to the switch drive electrode 202 serving as the charge injection electrode and the switch drive electrode 202 and the charge accumulation electrode 205 are put into a non-contact state, the leakage stops almost completely. Therefore, the deformation is held semi-permanently. However, when the cavity 235 between the upper signal line 217 and the lower signal line 218 in the basic attitude (see FIG. 20) is set to be smaller than the cavity 203 between the switch drive electrode 202 serving as the charge injection electrode and the charge accumulation electrode 205, the contact state between the upper signal line 217 and the lower electrode signal 218 remains to be held. More specifically, the contact state between the upper signal line 217 and the lower electrode signal 218 is held semi-permanently.

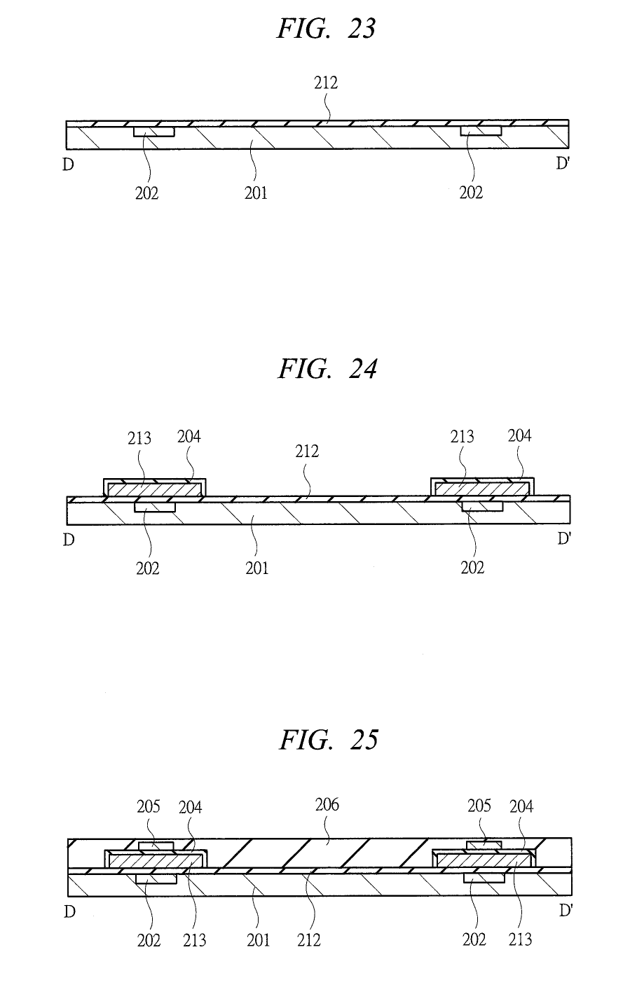

Next, a method for manufacturing the MEMS switch according to the second embodiment will be described. FIG. 23 to FIG. 30 are sectional views schematically showing the manufacturing process of the MEMS switch, wherein a drive portion 230 and a signal line portion 231 (line D-D′ in FIG. 19) are respectively shown. When the MEMS switch is provided together with a semiconductor integrated circuit, a step of forming the drive portion 230 in the MEMS switch SW according to the second embodiment is performed by utilizing a semiconductor manufacturing technology similar to the first embodiment and simultaneously with the formation of the semiconductor integrated circuit, and a step of forming the signal line portion 231 is performed after the formation of the semiconductor integrated circuit.

As shown in FIG. 23, first, after a diffusion layer serving as the switch drive electrode 202 is formed on the substrate 201 made of, for example, silicon through lithography and ion implantation process, a surface of the substrate 201 is oxidized to form the tunnel insulating film 212 with a film thickness of, for example, about 10 to 20 nm made of silicon oxide.

Subsequently, as shown in FIG. 24, after a sacrifice layer 213 made of, for example, polysilicon is formed in a region of the cavity 203 formed later, a surface thereof is oxidized to form the tunnel insulating film 204 with a film thickness of, for example, about 10 to 20 nm made of silicon oxide.

Subsequently, as shown in FIG. 25, the charge accumulation electrode 205 is formed on the sacrifice layer 213 having the tunnel insulating film 204 formed thereon, and the interlayer insulating film 206 is further deposited thereon.

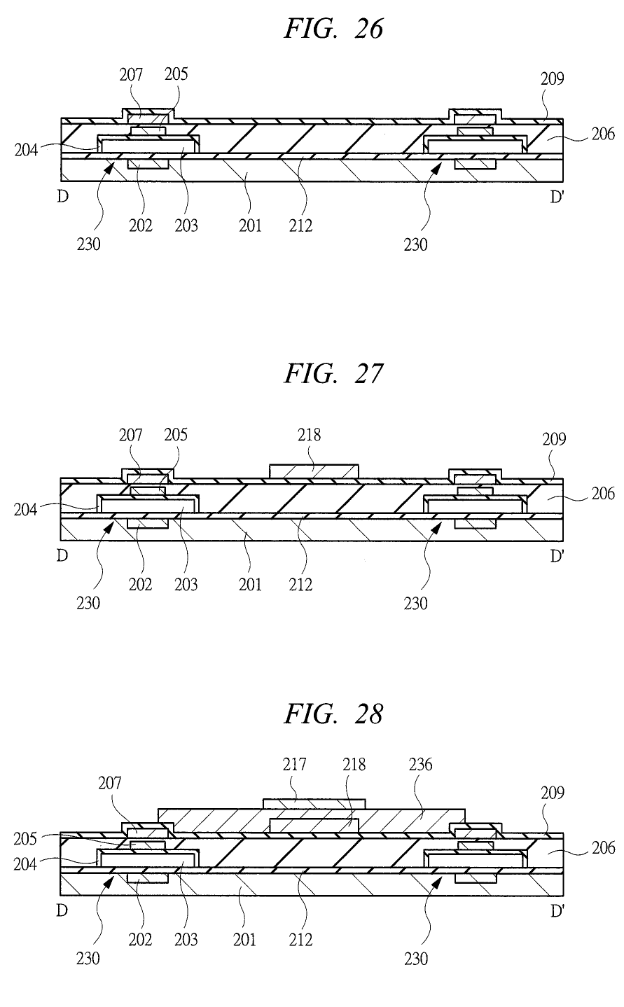

Subsequently, as shown in FIG. 26, after an etching hole (not shown) reaching the sacrifice layer 213 in the drive portion 230 is formed, the sacrifice layer 213 made of polysilicon is etched out via the etching hole to form the cavity 203. The sacrifice layer 213 is removed using XeF₂-gas phase etching. In this case, silicon oxide such as the tunnel insulating films 212 and the like are hardly etched. Next, after the sacrifice layer is etched, hydrophobic treatment is performed to an inner surface of the cavity 203. By this means, attachment between the switch drive electrode 202 and the tunnel insulating film 204 is prevented.

Subsequently, an insulating film (not shown) made of, for example, silicon oxide is deposited through CVD process to seal the etching hole, a switch drive electrode 207 made of, for example, polysilicon is formed. Note that it is not necessarily essential to seal the etching hole with an insulating film made of silicon oxide.

Subsequently, a whole surface of the substrate 201 is covered with a protective film 209 made of silicon nitride. All the processes used in the above are included in a scope of a manufacturing process of a so-called standard CMOS (complementary metal oxide semiconductor) semiconductor integrated circuit. That is, the MEMS switch according to the second embodiment can be manufactured through the manufacturing process of the standard CMOS semiconductor integrated circuit. Therefore, the MEMS switch according to the second embodiment can be easily integrated with a CMOS semiconductor integrated circuit in a monolithic manner. That is, when the MEMS switch according to the second embodiment is to be integrated with the CMOS semiconductor integrated circuit in a monolithic manner, the CMOS semiconductor integrated circuit is completed through the processes described above.

Subsequently, as shown in FIG. 27, the lower signal line 218 is formed on the protective film 209. A thin gold film is deposited on an upper surface of the lower signal line 218 by, for example, plating.

Subsequently, as shown in FIG. 28, a sacrifice layer 236 is formed using an organic resist in a region of the later-formed doubly-supported beam 211 except for its foot portion and in a region to be the cavity 235, and the upper signal line 217 is further formed thereon. A thin gold film is formed on a lower surface of the upper signal line 217.

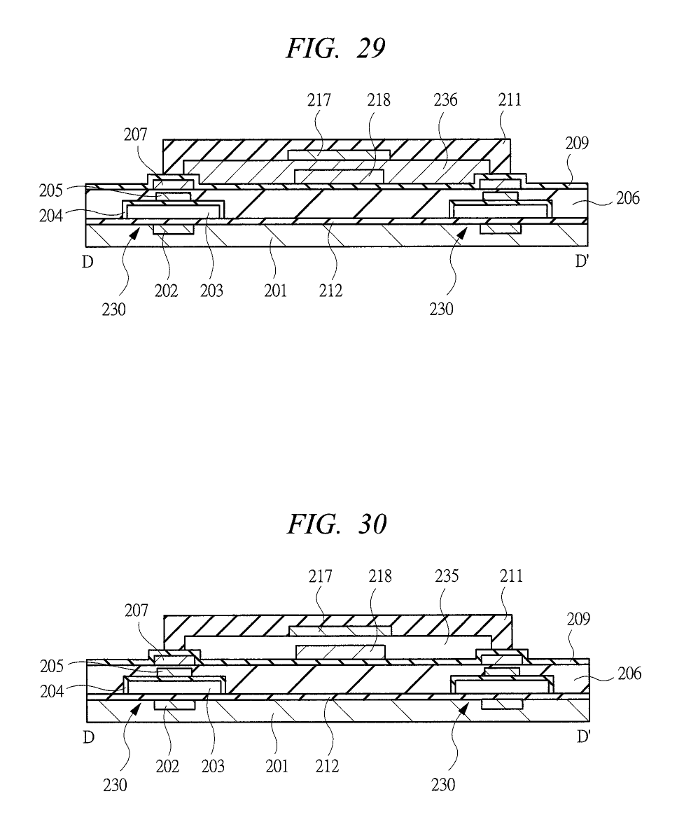

Subsequently, as shown in FIG. 29, an insulating film made of, for example, silicon oxide is deposited on a whole surface of the substrate 201, and the doubly-supported beam 211 made from the insulating film is formed.

Subsequently, as shown in FIG. 30, an etching hole (not shown) reaching the sacrifice layer 236 is formed in a proper region of the doubly-supported beam 211, and the sacrifice layer 236 made of organic resist is etched out via the etching hole, thereby forming the cavity 235. An insulating film made of silicon oxide is deposited again through CVD process to close the etching hole, thereby sealing the cavity.

According to the manufacturing method of the second embodiment, the CMOS semiconductor integrated circuit and the drive portion 230 produced by the manufacturing method thereof are completely separated from the forming step of the upper signal line 217 and the lower signal line 218 using gold by the protective film 209. More specifically, since gold atoms do not pass through the protective film 209 made of, for example, silicon nitride and diffuse to the CMOS semiconductor integrated circuit positioned below the protective film 209, transistor characteristics do not degrade.

Since a contact point between the upper signal line 217 and the lower signal line 218 is sealed in the cavity 235, degradation of a contact surface due to influence such as external moisture or chemical pollution can be suppressed.

As described above, according to the second embodiment, a small-sized bistable MEMS switch whose insertion loss is reduced, which is excellent in cutoff characteristic and anti-wearing characteristic at the signal line portion, whose structure is simple, whose holding state is stable for a long period, and which can be easily mounted together with a semiconductor integrated circuit can be provided. Also, since the upper signal line 217 and the lower signal line 218 and the switch drive electrodes 202 and 207 are independent from each other, a high frequency signal (RF signal) applied to, for example, the upper signal line 217 does not influence the driving of the switch.

### Third Embodiment

A MEMS switch according to a third embodiment and the MEMS switch according to the first embodiment are the same in structure but they are different in drive principle from each other. Thus, the description of the structure of the MEMS switch according to the third embodiment is omitted and the drive principle will be mainly described. The MEMS switch according to the third embodiment can be applied as a switch used for determining whether or not transmission of a signal is performed.

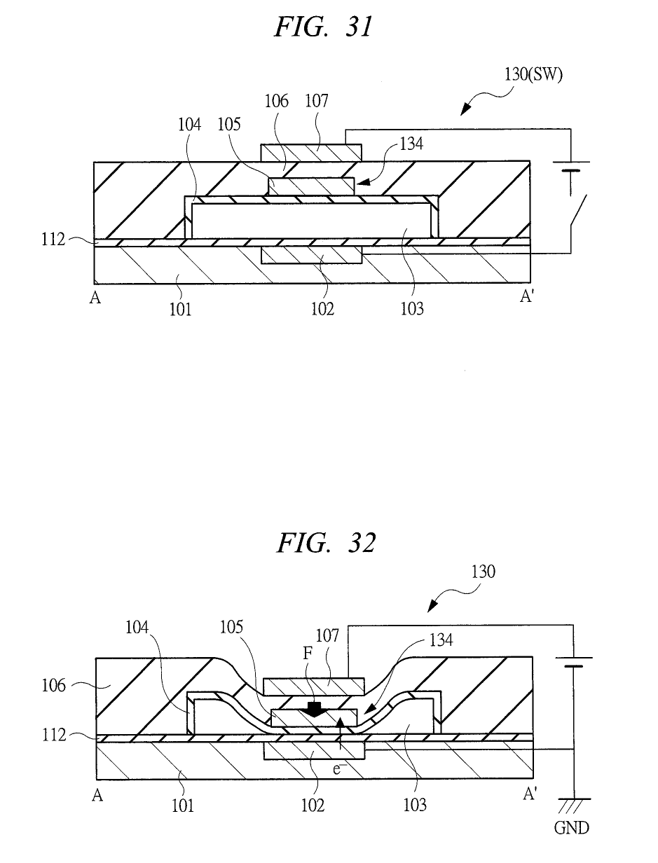

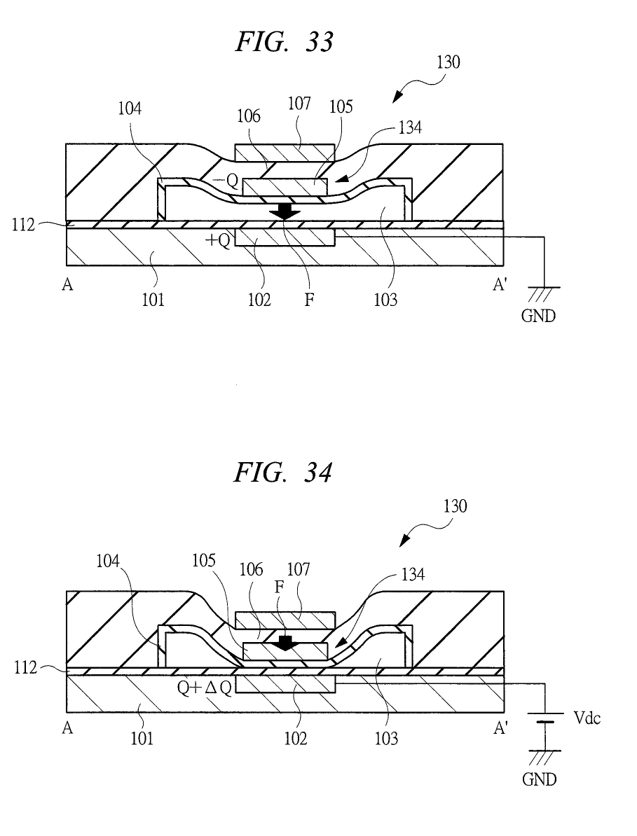

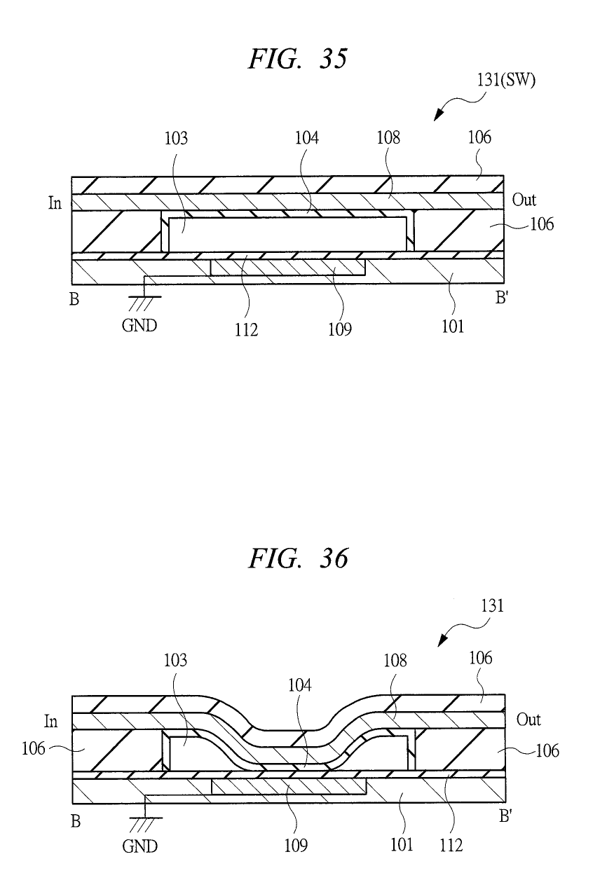

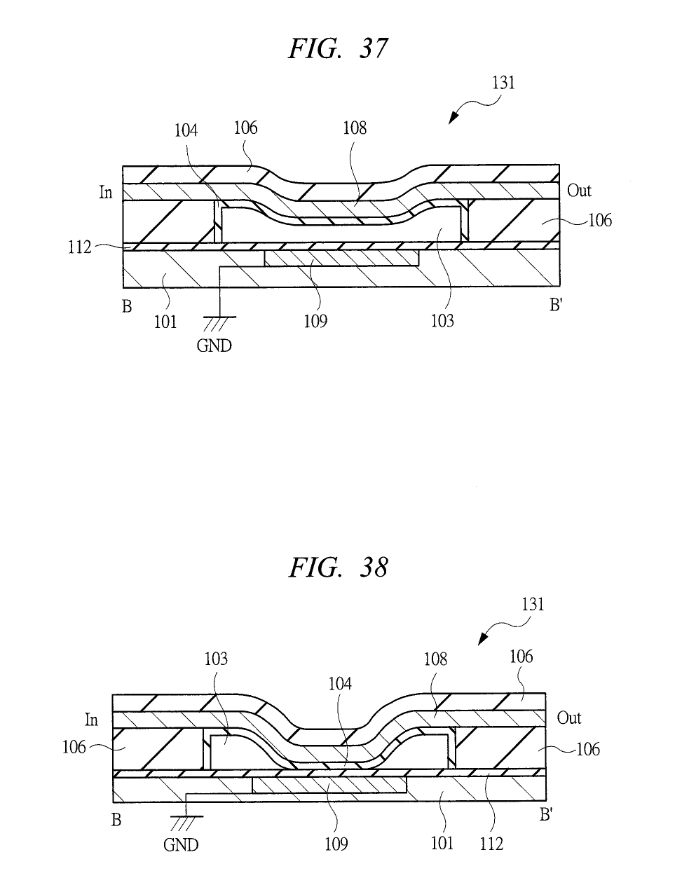

Since a planar structure of the MEMS switch according to the third embodiment is similar to that of the MEMS switch according to the first embodiment, the description will be made with reference to FIG. 1. FIG. 31 to FIG. 34 are sectional views taken along line A-A′ in FIG. 1 for describing a drive principle of the MEMS switch SW according to the third embodiment of the present invention, wherein FIG. 31 shows an initial state of the MEMS switch, FIG. 32 shows a charge injection state thereof, FIG. 33 shows a charge holding state and FIG. 34 shows a charge re-injection state. FIG. 35 to FIG. 38 are sectional views of the MEMS switch taken along line B-B′ in FIG. 1 for describing the drive principle of the MEMS switch SW according to the third embodiment of the present invention, wherein FIG. 35 shows an initial state of the MEMS switch SW, FIG. 36 shows a charge injection state thereof, FIG. 37 shows a charge holding state thereof, and FIG. 38 shows a charge re-injection state.

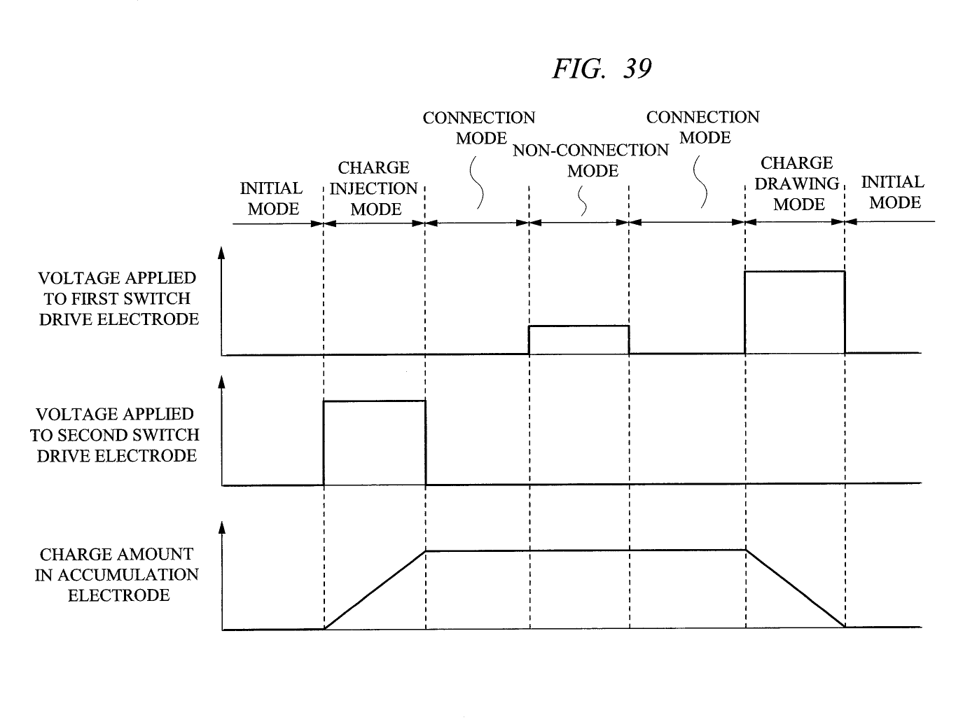

FIG. 39 is a timing chart schematically showing a drive voltage signal of the MEMS switch according to the third embodiment, where an applied voltage to the first switch drive electrode 102, an applied voltage to the second switch drive electrode 107, and a charge amount of the charge accumulation electrode 105 according to elapsed time are shown.

First, as shown in FIG. 31 and FIG. 35, in an initial state (a basic attitude) of the MEMS switch SW according to the third embodiment, the switch drive electrode 102 serving as a charge injection electrode and the tunnel insulating film 104 are put in a non-contact state with interposing the cavity 103 therebetween in a state where a voltage is not applied to the switch drive electrodes 102 and 107. At this time, the cavity 103 is present between the signal line 108 and the ground electrode 109. Accordingly, a capacitance between the signal line 108 and the ground GND is very small, and the input terminal In and the output terminal Out of the signal line 108 are put in AC connected state and DC connected state. This state is called “initial mode” (see FIG. 39).

Subsequently, as shown in FIG. 32, when the switch drive electrode 102 is grounded and a positive voltage is applied to the switch drive electrode 107 during a charge injection mode shown in FIG. 39 from the initial state of the MEMS switch, the whole diaphragm 134 above the cavity 103 is deformed by electrostatic force F, and the switch drive electrode 102 serving as the charge injection electrode and the charge accumulation electrode 105 contact with each other via the tunnel insulating films 112 and 104. In this case, electrons are injected from the switch drive electrode 102 serving as the charge injection electrode into the charge accumulation electrode 105 via the tunnel insulating films 112 and 104.

At this time, as shown in FIG. 36, the signal line 108 and the ground electrode 109 are connected to each other via the tunnel insulating film 104 and the tunnel insulating film 112. Therefore, a capacitance between the signal line 108 and the ground GND is increased, and the input electrodes In and the output electrode Out of the signal line 108 are put in an AC non-connected state (cutoff state), while the input terminal In and the ground GND are put in an AC connected state. This state is called “charge injection mode”.

Subsequently, as shown in FIG. 33, when voltage applied to the switch drive electrodes 102 and 107 is set to 0 V during the switch connected state holding period shown in FIG. 39, deformation is held due to electrostatic force F acting between charge (electrons) stored in the charge accumulation electrode 105 and charge with reversed polarity induced by electrostatic field generated by the electrons in the switch drive electrode 102 serving as the charge injection electrode. However, the degree of the deformation is decreased, and the switch drive electrode 102 serving as the charge injection electrode and the tunnel insulating film 104 are put into a non-contacted state. Accordingly, the charges in the charge accumulation electrode 105 do not leak to the switch drive electrode 102 side via the tunnel insulating films 112 and 104.

At this time, as shown in FIG. 37, when a surface of the ground electrode 109 is formed in an approximately the same surface as that of a surface of the switch drive electrode 102 serving as the charge injection electrode in the cavity 103, the signal line 108 and the ground electrode 109 are separated from each other via the tunnel insulating film 104, the sufficient cavity 103, and the tunnel insulating film 112 and the input terminal In and the output terminal Out of the signal line are put into an AC connected state. This state is called “connection mode”.

Subsequently, as shown in FIG. 34, when a voltage Vdc is applied to the switch drive electrode 102, a charge amount in the switch drive electrode 102 serving as the charge injection electrode is increased by ΔQ. The electrostatic force F between the switch drive electrode 102 and the charge accumulation electrode 105 is increased by electrostatic field (E) generated by the charge accumulated in the switch drive electrode 102 and the charge increment ΔQ (increment EΔQ), and the diaphragm 134 in the drive portion 130 is deformed. In this manner, the switch drive electrode 102 and the tunnel insulating film 104 contact with each other.

At this time, as shown in FIG. 38, the signal line 108 and the ground electrode 109 also contact with each other via the tunnel insulating film 104 and the tunnel insulating film 112. Therefore, a capacitance between the signal line 108 and the ground GND is increased and the input terminal In and the output terminal Out of the signal line 108 are put into an AC non-connected state. This state is called “non-connection mode”. When the voltage Vdc is returned back to 0 V, the switch returns back to the state shown in FIG. 33 and FIG. 37.

According to the MEMS switch of the third embodiment, since a high voltage between the switch drive electrode serving as the charge injection electrode and the charge accumulation electrode can be maintained by the accumulated charge without continuing to drive the voltage boosting circuit, large electrostatic force change can be obtained by a relatively small voltage signal, and the switch can be driven with a low voltage. The charge re-injection may be performed by generating a high voltage by the boosting circuit formed on the substrate on which the MEMS switch is formed, or it may be performed by applying high voltage from an external device.

The method for manufacturing the MEMS switch according to the third embodiment may be approximately similar to the method for manufacturing the MEMS switch according to the first embodiment shown in FIG. 10 to FIG. 15 except for the step of forming the ground electrode 109. More specifically, in the third embodiment, the ground electrode 109 can be formed simultaneously with the formation of the switch drive electrode 102.

Accordingly, a small-sized bistable MEMS switch whose structure is simple, which can be driven with a low voltage, whose holding state is stable for a long term, and which is easily mounted together with the semiconductor integrated circuit can be provided. Therefore, the MEMS switch can be held in a connected (or non-connected) state while suppressing the power consumption.

### Fourth Embodiment

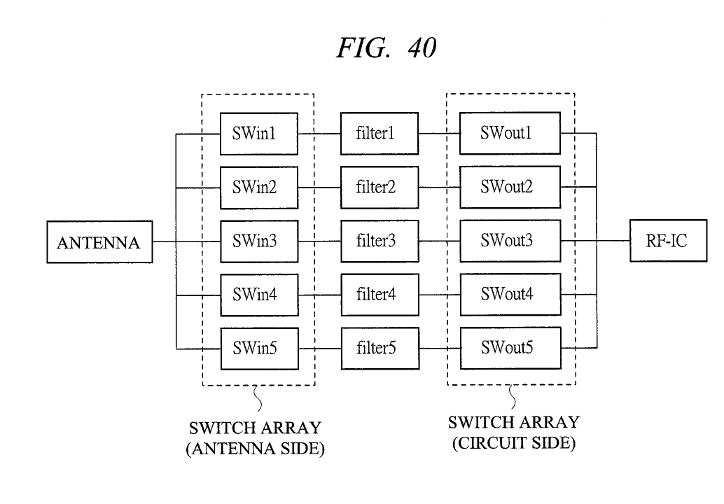

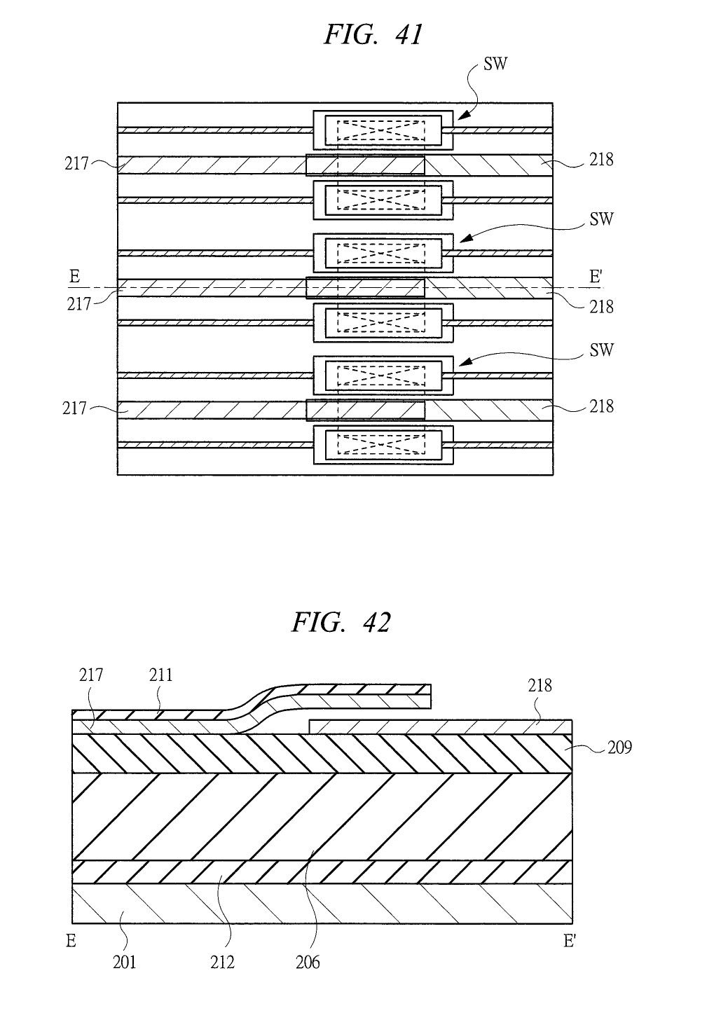

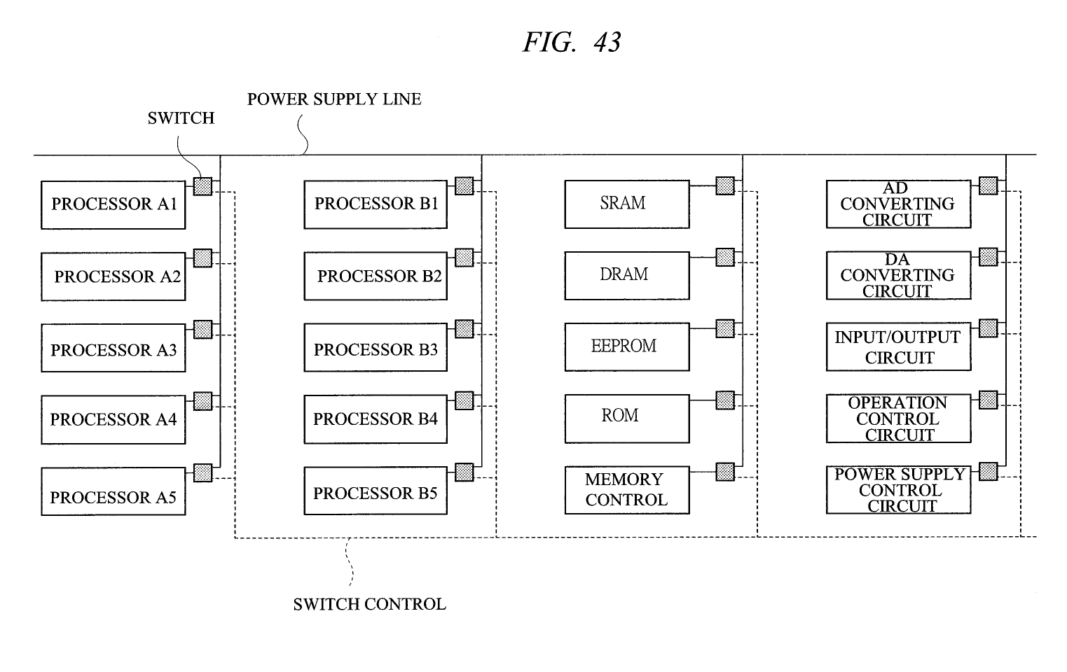

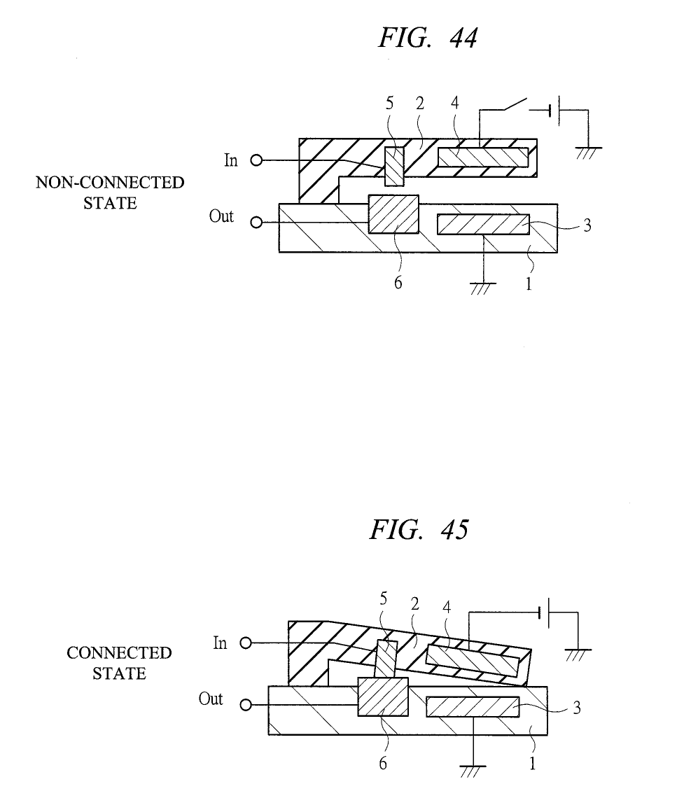

In a fourth embodiment of the present invention, a case where the MEMS switch according to the second embodiment is applied to a band selector switch of an RF front end module will be described. FIG. 40 is an explanatory diagram schematically showing a whole configuration of the RF front end module according to the fourth embodiment of the present invention. FIG. 41 is a plan view schematically showing a main portion of a switch array. FIG. 42 is a sectional view taken along line E-E′ in FIG. 41. Note that the description about the MEMS switch in the fourth embodiment will be omitted because it is similar to that of the second embodiment.

As shown in FIG. 40, an RF line from an antenna is branched into plural lines and then connected to a switch array on an antenna side. The switch array on the antenna side is composed of the MEMS switches SW described in the second embodiment arranged in an array, and the branched RF lines are connected to the respective MEMS switches SW. In order to maintain integrity in description below, the antenna side is called input here on the premise of reception. Outputs of respective MEMS switches SWin1, SWin2, . . . , SWin5 in the switch array on the antenna side are respectively connected to filters filter1, filter2, . . . , filter5 having different high frequency characteristics, and outputs of the respective filters are connected to inputs of respective switches SWout1, SWout2, . . . , SWout5 of the switch array on the circuit side. An output of the switch array on the circuit side is connected to an RF semiconductor integrated circuit (RF-IC) for reception. All the MEMS switches described above are mounted together with the RF semiconductor integrated circuit in a monolithic manner. However, external parts are used as the filters here. Although it is also possible to mount the RF filters together with the switches or the RF semiconductor integrated circuit, the method thereof will be omitted.

### Fifth Embodiment

In a fifth embodiment of the present invention, a case where the MEMS switches according to the first embodiment are applied to selector switches for power supply lines to respective circuit blocks in a system LSI will be described. FIG. 43 is an explanatory diagram schematically showing a whole configuration of a system LSI according to the fifth embodiment.

As shown in FIG. 43, for example, five processors A, five processors B, an SRAM, a ROM, an EEPROM, and circuit blocks such as an AD converting circuit, a DA converting circuit, and an input/output control circuit are included. Power is supplied to respective circuits via power supply lines.

In the fifth embodiment, the MEMS switches according to the first embodiment are disposed at interface portions from a common power supply line to the power supply lines in the respective circuit blocks. By putting only a power supply switch to a circuit block to be used into a connected state, power consumption due to transistor leakage current or the like in a circuit block which is not used can be suppressed substantially completely.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the first embodiment, the case where injection and drawing of charge to and from the charge accumulation electrode are performed using a Fowler-Nordheim current has been described, but they may be performed by the hot carrier injection.

The present invention can be utilized for various applications such as a switch for antenna selection or a band selection, a switch for circuit block selection in a semiconductor integrated circuit, a switch for dynamic chip re-configuration, and all MEMS logic circuits where these switches are used as a logic element itself in the high frequency technology.

What is claimed is:

1. A switch using a micro electro mechanical system comprising:
a substrate;
a movable portion which is disposed near said substrate and above said substrate;
a pair of switch drive electrodes which are disposed on said substrate and said movable portion, respectively;
a charge accumulation electrode which is disposed between said pair of switch drive electrodes; and
a signal line portion having a first signal line fixed on said substrate and a second signal line fixed on said movable portion,
wherein a signal transmits through said signal line portion in accordance with electrical connection or disconnection between said first signal line and said second signal line,
said signal line portion and said pair of switch drive electrodes are arranged so that they do not overlap with each other in a region parallel to said substrate, and
said movable portion is elastically deformed by electrostatic field generated by accumulating charge in said charge accumulation electrode, thereby changing and holding a connection state of said first signal line and said second signal line.

2. The switch using a micro electro mechanical system according to claim 1,
wherein a charge injection electrode which performs writing and erasing of charge into and from said charge accumulation electrode and which comprises said switch drive electrode on a substrate side or said switch drive electrode on a movable portion side and said charge accumulation electrode are disposed with interposing a cavity present between said movable portion and said substrate,
when a voltage is applied to said pair of switch drive electrodes, said movable portion is deformed by electrostatic force, and
said charge injection electrode and said charge accumulation electrode contact with each other via a tunnel insulating film comprising at least one of a first insulating film disposed on said substrate and a second insulating film disposed on said movable portion, thereby injecting electrons from said charge injection electrode to said charge accumulation electrode.

3. The switch using a micro electro mechanical system according to claim 1,
wherein said charge accumulation electrode is disposed on said movable portion side.

4. The switch using a micro electro mechanical system according to claim 1,
wherein said charge accumulation electrode is disposed on said substrate side.

5. The switch using a micro electro mechanical system according to claim 1,
wherein a drive portion including said pair of switch drive electrodes and said signal line portion are formed through semiconductor integrated circuit process in a monolithic manner.

6. A switch using a micro electro mechanical system comprising:
a substrate; and
a movable portion which is disposed above said substrate so as to be opposed to said substrate with interposing a cavity therebetween and is elastically deformable,
wherein a drive portion for performing a switch drive includes:
a first electrode which is disposed on said substrate and deforms said movable portion;
a second electrode which is disposed on said movable portion and deforms said movable portion;
a third electrode which is disposed on said substrate or said movable portion between said first electrode and said second electrode and accumulates charge; and
a tunnel insulating film comprising at least one of a first insulating film provided on a cavity side of said substrate between said first electrode and said cavity and a second insulating film provided on a cavity side of said movable portion between said second electrode and said cavity.

7. The switch using a micro electro mechanical system according to claim 6,
wherein said drive portion further includes:
an interlayer insulating film which is disposed on said movable portion between said third electrode and said second electrode disposed on said movable portion and is thicker than said tunnel insulating film in a thickness direction of said substrate.

8. The switch using a micro electro mechanical system according to claim 7,
wherein writing of electrons from said first electrode to said third electrode is performed via said tunnel insulating film.

9. The switch using a micro electro mechanical system according to claim 7,
wherein, when a voltage is applied between said first electrode and said second electrode, said movable portion is deformed by electrostatic force, and
said first electrode and said third electrode contact with each other via said tunnel insulating film, thereby injecting electrons from said first electrode to said third electrode.

10. The switch using a micro electromechanical system according to claim 6, further comprising:
an interlayer insulating film which is disposed on said substrate between said third electrode and said first electrode disposed on said substrate and is thicker than said tunnel insulating film in a thickness direction of said substrate.

11. The switch using a micro electro mechanical system according to claim 10,
wherein injection of electrons from said second electrode to said third electrode is performed via said tunnel insulating film.

12. The switch using a micro electro mechanical system according to claim 10,
wherein, when a voltage is applied between said first electrode and said second electrode, said movable portion is deformed by electrostatic force, and
said second electrode and said third electrode contact with each other via said tunnel insulating film, thereby writing electrons from said second electrode to said third electrode.

13. A switch using a micro electro mechanical system comprising:
a substrate;
a movable portion which is disposed above said substrate so as to be opposed to said substrate with interposing a cavity therebetween and is elastically deformable;
a signal line portion for transmitting a signal; and
a drive portion which sandwiches said signal line portion in a region parallel with said substrate and performs a switch drive,
wherein said drive portion includes:
a first electrode which is disposed on said substrate and deforms said movable portion;
a second electrode which is disposed on said movable portion and deforms said movable portion,
a third electrode which is disposed on said substrate or said movable portion between said first electrode and said second electrode and accumulates charge; and
a tunnel insulating film comprising at least one of a first insulating film provided on a cavity side of said substrate between said first electrode and said cavity and a second insulating film provided on a cavity side of said movable portion between said second electrode and said cavity.

14. The switch using a micro electro mechanical system according to claim 13,
wherein said third electrode is disposed on said movable portion,
said signal line portion has a first signal line which is disposed on said substrate at a position higher than said first electrode in a thickness direction of said substrate and a second signal line which is disposed on said movable portion and provided in the same layer as said third electrode, and
said movable portion is deformed by electrostatic force generated by accumulating charge in said third electrode, and a signal transmits through said signal line portion in accordance with electric connection or non-connection between said first signal line and said second signal line.

15. The switch using a micro electro mechanical system according to claim 13,
wherein said third electrode is disposed on said substrate,
said signal line portion has a first signal line which is disposed on said substrate at a position higher than said third electrode in a thickness direction of said substrate and a second signal line which is disposed on said movable portion and provided in the same layer as said first electrode, and
said movable portion is deformed by electrostatic field generated by accumulating charge in said third electrode, and a signal transmits through said signal line portion in accordance with electric connection or non-connection between said first signal line and said second signal line.

16. The switch using a micro electro mechanical system according to claim 13,
wherein said signal line portion contains gold,
a protective film for preventing said gold from diffusing toward a drive portion side is disposed on an upper portion of said drive portion in a thickness direction of said substrate, and
said signal line portion is disposed on an upper portion of said protective film.
